(19) United States
(12) Patent Application Publication
(10) Pub. No.: US 2026/0293313 A1
(43) Pub. Date: Sep. 24, 2026

(54) SEMICONDUCTOR DEVICE, DISPLAY DEVICE, AND METHOD FOR MANUFACTURING SEMICONDUCTOR DEVICE

(71) Applicant: Sharp Display Technology Corporation, Kameyama City (JP)

(72) Inventors: Shinji NAKAJIMA, Kameyama City (JP); Kazuhiko IWASA, Kameyama City (JP); Masamitsu YAMANAKA, Kameyama City (JP); Yutaka SAWAYAMA, Kameyama City (JP); Yoshimasa CHIKAMA, Kameyama City (JP)

(21) Appl. No.: 19/564,589

(22) Filed: Mar. 12, 2026

(30) Foreign Application Priority Data
Mar. 18, 2025 (JP) 2025-043365

(51) Int. Cl. H10D 86/40; H10D 86/01; H10D 86/60

(52) U.S. Cl. CPC H10D 86/451; H10D 86/0231; H10D 86/423; H10D 86/60

(57) ABSTRACT

A semiconductor device comprises a semiconductor portion formed from a part of a semiconductor film; and a first insulating film disposed in a higher layer than the semiconductor film and containing at least silicon and oxygen, wherein the first insulating film includes a first layer, and a second layer positioned in a higher layer than the first layer and having a lower content of the oxygen than the first layer.

### BACKGROUND

### Technical Field

The technique disclosed in the Specification relates to a semiconductor device, a display device, and a method for manufacturing the semiconductor device in all of which hydrogen and other things are less likely to diffuse into a semiconductor portion.

Japanese Unexamined Patent Application Publication No. 2020-43347 discloses a conventionally known semiconductor device by way of example. In a thin-film transistor that is the semiconductor device described in Japanese Unexamined Patent Application Publication No. 2020-43347, a silicon oxide layer containing many defects, which are represented by dangling bonds, is formed in contact with an oxide semiconductor layer, and impurities contained in the oxide semiconductor layer, such as hydrogen and moisture (hydrogen atoms, and compounds containing hydrogen atoms, such as H₂O) are diffused into the silicon oxide layer, thereby reducing the concentration of the impurities within the oxide semiconductor layer. Further, a mixed region is provided at the interface between the oxide semiconductor layer and silicon oxide layer.

### SUMMARY

In the thin-film transistor described in Japanese Unexamined Patent Application Publication No. 2020-43347, the silicon oxide layer containing many defects is formed so as to be in direct contact with the oxide semiconductor layer.

Hence, although the impurities, such as hydrogen and moisture, contained in the oxide semiconductor layer are more likely to diffuse into the silicon oxide layer, but upon a heat treatment, such as annealing, the impurities, such as hydrogen and moisture, diffused in the silicon oxide layer may possibly diffuse again into the oxide semiconductor layer.

The technique described in the Specification has been completed based on the above circumstances, and it is an object of the technique to make hydrogen and other things less likely to diffuse into the semiconductor portion.

(1) A semiconductor device related to the technique described in the Specification includes the following: a semiconductor portion formed from a part of a semiconductor film; and a first insulating film disposed in a higher layer than the semiconductor film and containing at least silicon and oxygen. The first insulating film includes a first layer, and a second layer positioned in a higher layer than the first layer and having a lower content of the oxygen than the first layer.

(2) Further, in the semiconductor device in addition to (1), the first insulating film may include a third layer positioned in a higher layer than the second layer and having a higher content of the oxygen than the second layer.

(3) Further, in the semiconductor device in addition to (2), the third layer may have a content of the oxygen equal to a content of the oxygen of the first layer.

(4) Further, the semiconductor device may include, in addition to any of (1) to (3), a second insulating film disposed in a higher layer than the first insulating film and containing at least silicon and nitrogen.

(5) Further, in the semiconductor device in addition to any of (1) to (4), the first layer may be thicker than the second layer.

(6) Further, the semiconductor device may include the following in addition to any of (1) to (5): a third insulating film disposed in a higher layer than the semiconductor film and in a lower layer than the first insulating film; a first electrode formed from a part of a first metal film disposed in a higher layer than the third insulating film and in a lower layer than the first insulating film; a second electrode formed from a part of a second metal film disposed in a higher layer than the first insulating film; and a low-resistance portion formed from a part of the semiconductor film, coupling to the semiconductor portion, and processed to have a lower resistance than the semiconductor portion. The first electrode may be disposed so as to overlap the semiconductor portion. The third insulating film may be disposed so as to overlap the semiconductor portion and the first electrode. The second electrode may be disposed so as to overlap at least a part of the low-resistance portion. A contact hole connecting the second electrode and the low-resistance portion together may be provided in the first insulating film overlapping both of the second electrode and the low-resistance portion.

(7) Further, the semiconductor device may include the following in addition to any of (1) to (5): a fourth insulating film disposed in a lower layer of the semiconductor film; a third electrode formed from a part of a third metal film disposed in a lower layer than the fourth insulating film; and a fourth electrode formed from a part of a fourth metal film disposed in a higher layer than the semiconductor film and in a lower layer than the first insulating film. The third electrode may be disposed so as to overlap the semiconductor portion. The fourth electrode may be disposed so as to overlap a part of the semiconductor portion to be in contact with the semiconductor portion.

(8) Further, in the semiconductor device in addition to any of (1) to (7), the second layer may be amorphous.

(9) A display device related to the technique described in the Specification includes the following: the semiconductor device according to any of (1) to (8); and a counter substrate disposed so as to face the semiconductor device.

(10) A method for manufacturing a semiconductor device related to the technique described in the Specification includes the following: providing a semiconductor portion by forming a semiconductor film, followed by patterning the semiconductor film as formed; and providing, in a higher layer than the semiconductor film, a first insulating film containing at least silicon and oxygen. The providing of the first insulating film is forming a first layer, followed by forming, in a higher layer than the first layer, a second layer having a lower content of the oxygen than the first layer.

(11) Further, in the method for manufacturing the semiconductor device in addition to (10), the providing of the first insulating film may be supplying at least a silane gas, a nitrous oxide gas, and a noble gas as raw materials to a chemical-vapor-deposition apparatus to form the first layer, followed by supplying at least the silane gas and the noble gas as raw materials to the chemical-vapor-deposition apparatus to form the second layer.

(12) Further, in the method for manufacturing the semiconductor device in addition to (11), the providing of the first insulating film may be, after forming the second layer, supplying at least the silane gas, the nitrous oxide gas, and the noble gas as raw materials to the chemical-vapor-deposition apparatus to form, in a higher layer than the second layer, a third layer having a higher content of the oxygen than the second layer.

The technique described in the Specification can make hydrogen and other things less likely to diffuse into the semiconductor portion.

### BRIEF DESCRIPTION OF DRAWINGS

FIG. 1 is a plan view of a liquid crystal panel, a driver, and a flexible substrate all constituting a liquid crystal display according to the first embodiment;

FIG. 2 is a cross-sectional view of the liquid crystal panel, driver, and flexible substrate according to the first embodiment;

FIG. 3 is a circuit diagram of the electrical configuration of an array substrate constituting the liquid crystal panel according to the first embodiment;

FIG. 4 is a cross-sectional view of a TFT in the array substrate according to the first embodiment;

FIG. 5 is a cross-sectional view of the array substrate according to the first embodiment with a first metal film patterned together with a gate insulating film after a fourth step, which is included in a method for manufacturing the array substrate, and FIG. 5 is a cross-sectional view taken along the same line as that in FIG. 4;

FIG. 6 is a cross-sectional view of the array substrate according to the first embodiment with a first layer of a first interlayer insulating film formed in a fifth step, which is included in the method for manufacturing the array substrate, and FIG. 6 is a cross-sectional view taken along the same line as that in FIG. 4;

FIG. 7 is a cross-sectional view of the array substrate according to the first embodiment with a second layer of the first interlayer insulating film formed in the fifth step, which is included in the method for manufacturing the array substrate, and FIG. 7 is a cross-sectional view taken along the same line as that in FIG. 4;

FIG. 8 is a cross-sectional view of the array substrate according to the first embodiment with a third layer of the first interlayer insulating film formed in the fifth step, which is included in the method for manufacturing the array substrate, and FIG. 8 is a cross-sectional view taken along the same line as that in FIG. 4;

FIG. 9 is a cross-sectional view of the array substrate according to the first embodiment with a second interlayer insulating formed after a sixth step, which is included in the method for manufacturing the array substrate, and FIG. 9 is a cross-sectional view taken along the same line as that in FIG. 4; and

FIG. 10 is a cross-sectional view of a TFT in an array substrate according to a second embodiment.

### DESCRIPTION OF EMBODIMENTS

### First Embodiment

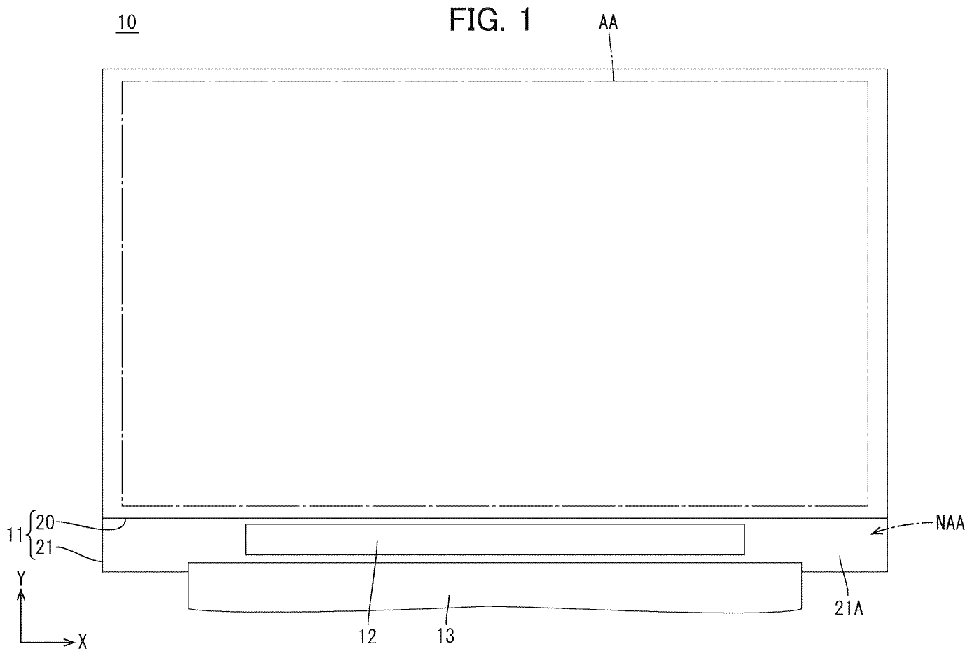

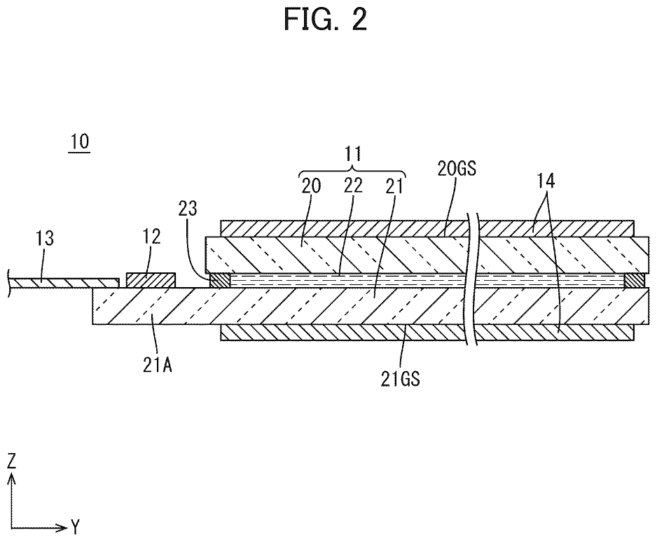

A first embodiment will be described with reference to FIGS. 1 to 9. This embodiment will describe a liquid crystal display device 10 by way of example. It is noted that some of the drawings show X-, Y-, and Z-axes; these axes are shown in such a manner that the directions of the individual axes correspond to the respective directions shown in each drawing. It is also noted that the upper sides of FIGS. 2 and 4 to 9 are defined as the front side of the liquid crystal display device 10, and the lower sides of the same are defined as the back side of same.

The liquid crystal display device 10 at least includes the following, as illustrated in FIG. 1: a liquid crystal panel (display device, display panel) 11 having a horizontally long rectangular shape and capable of displaying an image; and a backlight device (lighting device) that irradiates the liquid crystal panel 11 with light that is to be used for display. The backlight device is disposed on the back side (rear side) of the liquid crystal panel 11 and includes, but not limited to, a light source (e.g., an LED) that emits white light, and an optical member that converts light from the light source into planar light by applying an optical effect to the light. The liquid crystal panel 11 has a display region AA at the middle of its main surface; in the display region AA, an image is displayed. On the other hand, the frame-shaped perimeter portion surrounding the display region AA on the main surface of the liquid crystal panel 11 is a non-display region NAA, in which an image is not displayed.

The liquid crystal panel 11 will be described with reference to FIG. 2 as well as FIG. 1. The liquid crystal panel 11 is formed by joining a pair of substrates 20, and 21, as illustrated in FIGS. 1 and 2. One of the pair of substrates 20 and 21 on the front side is a counter substrate 20, and the other on the back side is an array substrate (semiconductor device) 21. The counter substrate 20 and the array substrate 21 are each formed by stacking various films on the inner-surface side of a light-transparent glass substrate (light-transparent substrate) 20GS and 21GS. Between the pair of substrates 20 and 21 is a liquid crystal layer 22 including liquid crystal molecules, which are substances whose optical property changes upon field application. Between the outer periphery ends of the pair of substrates 20 and 21 is a seal portion 23 sealing the liquid crystal layer 22. The seal portion 23 is formed in a rectangular frame shape so as to surround the liquid crystal layer 22. It is noted that polarization plates 14 are attached to the respective outer surfaces of both substrates 20 and 21.

As illustrated in FIGS. 1 and 2, the shorter sides of the counter substrate 20 are shorter than the shorter sides of the array substrate 21. The counter substrate 20 is joined to the array substrate 21 in such a manner that one end in the shorter side direction (Y-axis direction) is aligned with respect to the array substrate 21. Thus, the other end of the array substrate 21 in the shorter side direction is an exposed portion 21A protruding and exposed sideward from the counter substrate 20. The exposed portion 21A is the non-display region NAA in its entirety, and on the exposed portion 21A, a driver 12 for supplying various signals and a flexible substrate 13 are mounted.

The driver 12 is formed from an LSI chip incorporating a driver circuit. The driver 12 is mounted on the exposed portion 21A of the array substrate 21 through chip-on-glass (COG). The driver 12 processes various signals transmitted by the flexible substrate 13. As illustrated in FIGS. 1 and 2, the driver 12 is disposed so as to be adjacent to one side of the display region AA in the Y-axis direction and is sandwiched between the flexible substrate 13 and display region AA, which will be described below. The driver 12 has a horizontally long rectangular shape in plan view. The driver 12 can supply various signals to the source wiring lines 27 and other lines provided in the array substrate 21. The flexible substrate 13 is formed by forming a plurality of wiring patterns on a base material made of insulating and flexible synthetic resin (e.g., polyimide resin). The flexible substrate 13 has one end connected to the exposed portion 21A of the array substrate 21, and the other end connected to an external circuit board (e.g., a control board).

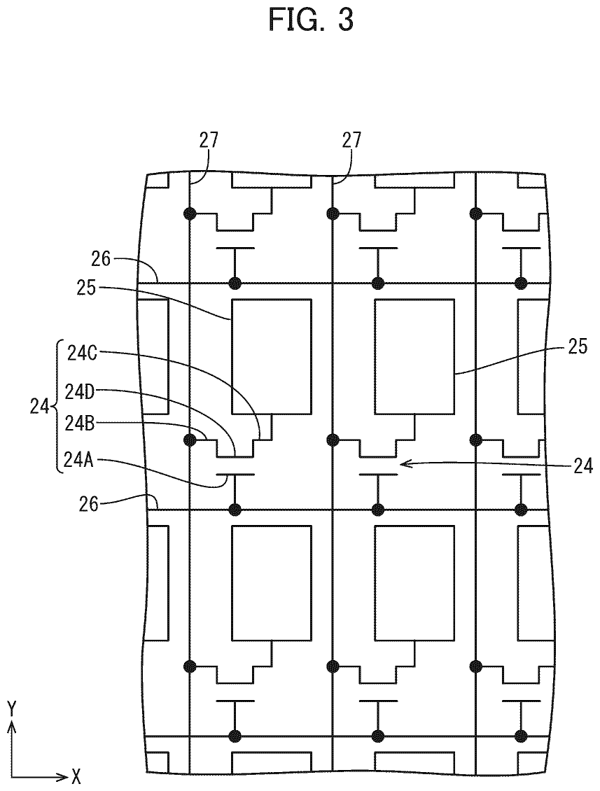

Next, the configuration of the display region AA of the array substrate 21 will be described with reference to FIG. 3. As illustrated in FIG. 3, TFTs (transistors, switching elements) 24 and pixel electrodes 25 are at least provided on the inner surface of the display region AA of the array substrate 21. A plurality of TFTs 24 and a plurality of pixel electrodes 25 are arranged in matrix (in rows and columns) at intervals along the X-axis and Y-axis directions. Around these TFTs 24 and pixel electrodes 25 is gate wiring lines (scanning wiring lines) 26 and source wiring lines (image wiring lines, signal wiring lines) 27 provided so as to be orthogonal to (cross) each other. The gate wiring lines 26 extend along the X-axis direction and a plurality of gate wiring lines 26 is arranged at intervals in the Y-axis direction. The source wiring lines 27 extend along the Y-axis direction and a plurality of source wiring lines 27 is arranged at intervals in the X-axis direction.

Each TFT 24 includes the following as illustrated in FIG. 3: a gate electrode (first electrode) 24A connected to the gate wiring line 26; a source electrode (second electrode) 24B connected to the source wiring line 27; a drain electrode (second electrode) 24C connected to the pixel electrode 25; a semiconductor portion 24D; and a low-resistance portion 24E connected to the source electrode 24B, drain electrode 24C, and semiconductor portion 24D. The TFT 24 is driven based on a scanning signal supplied to the gate electrode 24A by the gate wiring line 26. The scanning signal includes a potential (high potential) higher than the threshold voltage of the TFT 24. Accordingly, a channel region is produced in the semiconductor portion 24D, and thus, a potential based on an image signal supplied to the source electrode 24B by the source wiring line 27 is supplied to the drain electrode 24C via the channel region of the semiconductor portion 24D and the low-resistance portion 24E. As a result, the pixel electrode 25 is charged to the potential based on the image signal.

The configuration of the TFT 24 will be detailed later on.

Further, the display region AA of the counter substrate 20 includes a plurality of color filters provided in positions facing the individual pixel electrodes 25 on the array substrate 21. The color filters include three colors, i.e., red (R), green (G), and blue (B), arranged repeatedly side by side in a predetermined order, and together with the pixel electrodes 25, the color filters constitute the pixels of the respective colors (i.e., red pixels, green pixels, and blue pixels). The three pixels, i.e., the red, green, and blue pixels constitute a display pixel that enables color display with a predetermined gradation. A light-blocking portion (black matrix) for avoiding color mixture is formed between the color filters in the display region AA of the counter substrate 20. Further, either the counter substrate 20 or array substrate 21 is provided with a common electrode made of transparent electrode material similar to that of the pixel electrodes 25, and disposed so as to overlap the pixel electrodes 25 at intervals. The liquid crystal panel 11 can cause each pixel to display a predetermined gradation by applying a predetermined electric field to the liquid crystal layer 22 on the basis of a potential difference generated between the common electrode and the corresponding pixel electrode 25. It is noted that alignment films (not shown) for aligning the liquid crystal molecules included in the liquid crystal layer 22 are formed on the respective innermost surfaces (the uppermost surfaces) of both substrates 20 and 21 being in contact with the liquid crystal layer 22.

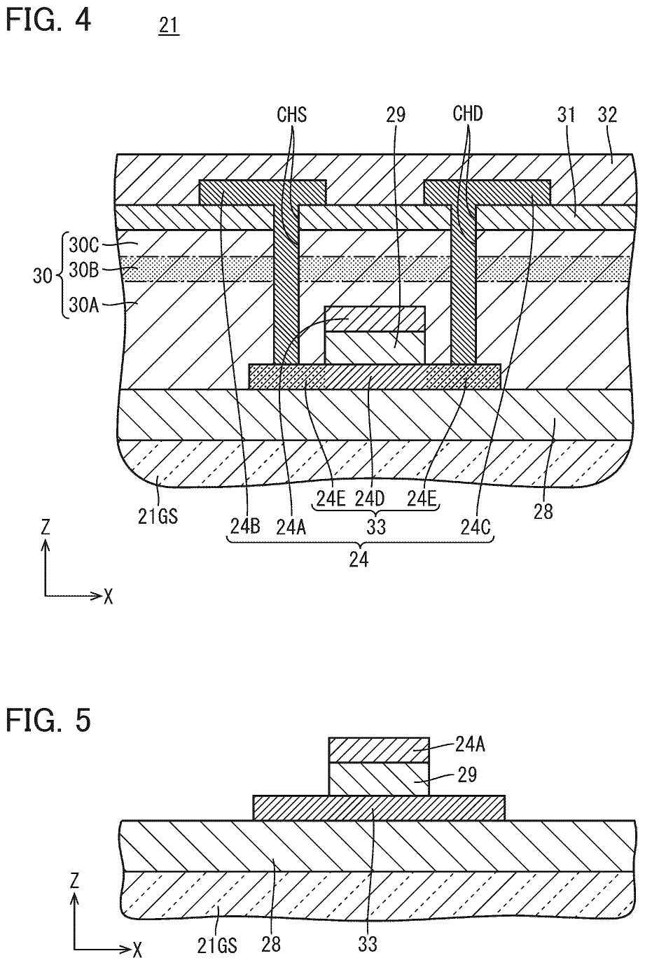

Next, various films stacked on the glass substrate (substrate) 21GS of the array substrate 21 will be detailed with reference to FIG. 4. On the glass substrate 21GS of the array substrate 21, at least the following films are stacked sequentially from the bottom (from the glass substrate 21GS), as illustrated in FIG. 4: a base coat film 28, a semiconductor film, a gate insulating film (third insulating film) 29, a first metal film, a first interlayer insulating film (first insulating film) 30, a second interlayer insulating film (second insulating film) 31, a second metal film, and a protective film (third interlayer insulating film) 32. It is noted that other than the foregoing films, a transparent electrode film disposed in a higher layer than the protective film 32 to constitute the pixel electrodes 25, an alignment film disposed on the innermost surface (uppermost layer) of the array substrate 21 to align the liquid crystal molecules, and other components are formed on the glass substrate 21GS of the array substrate 21.

Each of the first and second metal films is a monolayer film made of a single kind of metal material, a multilayer film made of different kinds of metal material (conductive material), or an alloy, and thus, each of these films has conductivity and light-blocking capability. The first metal film is, for example, a monolayer film of molybdenum tungsten (MoW), or a multilayer film of tungsten (W)-tantalum nitride (TaN). The first metal film constitutes, but not limited to, the gate wiring lines 26 and the gate electrodes 24A. The second metal film is, for instance, a multilayer film of titanium (Ti)-aluminum (Al)—Ti. The second metal film constitutes, but not limited to, the source wiring lines 27, the source electrodes 24B, and the drain electrodes 24C.

The semiconductor film is made of oxide semiconductor material.

More specifically, the semiconductor film is formed from, for example, a thin oxide film containing indium (In), gallium (Ga), and zinc (Zn), which are kinds of oxide semiconductors. The thin oxide film containing indium (In), gallium (Ga), and zinc (Zn) is amorphous or crystalline. The oxide semiconductor material of the semiconductor film has a higher resistance value in a state where no voltage is applied (OFF state), than a silicon semiconductor material. In addition, the oxide semiconductor material of the semiconductor film has a higher electron mobility than an amorphous silicon semiconductor material. The semiconductor film constitutes, but not limited to, the semiconductor portions 24D and the low-resistance portions 24E.

As illustrated in FIG. 4, each TFT 24 according to this embodiment includes a semiconductor pattern portion 33 formed by patterning the semiconductor film. The semiconductor pattern portion 33 constitutes the semiconductor portion 24D and low-resistance portion 24E of the TFT 24. The semiconductor pattern portion 33 is partly processed into a resistance reduced part (conductor). A part of the semiconductor pattern portion 33 undergone no resistance reduction (non-resistance-reduced part) constitutes the semiconductor portion 24D. The resistance reduced part of the semiconductor pattern portion 33 constitutes the low-resistance portion 24E. It is noted that FIG. 4 illustrates the low-resistance portion 24E, which is the resistance reduced part of the semiconductor pattern portion 33, denoted by a hatch. The semiconductor portion 24D, which is the part of the semiconductor pattern portion 33 undergone no resistance reduction, allows charges to move only under a specific condition (i.e., only when a high potential of the scanning signal is supplied to the gate electrode 24A). That is, the semiconductor portion 24D functions as a channel region under the specific condition. The semiconductor portion 24D, which is the part of the semiconductor pattern portion 33 undergone no resistance reduction, has a sheet resistance of, for instance, about 10⁶ to 10⁷ Ω/Q. On the other hand, the low-resistance portion 24E, which is the resistance reduced part of the semiconductor pattern portion 33, always enables charge movement and functions as a conductor. The low-resistance portion 24E, which is the resistance reduced part of the semiconductor pattern portion 33, has a sheet resistance of, for instance, about 10³ Ω/Q. That is, the low-resistance portion 24E, which is the resistance reduced part of the semiconductor pattern portion 33, has a lower resistivity than the semiconductor portion 24D; the resistivity stands at about 1/1000 to 1/10000 of that of the semiconductor portion 24D.

The semiconductor pattern portion 33 undergoes resistance reduction (processing into a conductor) by the use of the gate electrode 24A as a mask in a process step for producing the array substrate 21. Through this resistance reduction, a part (i.e., low-resistance portion 24E) of the semiconductor pattern portion 33 not overlapping the gate electrode 24A and thus not covered with the gate electrode 24A is processed into a low-resistance part. Examples of the resistance reduction include doping by the use of ion species, such as boron (B) and phosphorus (P), and annealing. A part (i.e., semiconductor portion 24D) of the semiconductor pattern portion 33 overlapping the gate electrode 24A and thus covered with the gate electrode 24A is not processed into a low-resistance part even when the resistance reduction is performed, because this part is masked by the gate electrode 24A.

The base coat film 28, the gate insulating film 29, the first interlayer insulating film 30, the second interlayer insulating film 31, and the protective film 32 are each made of inorganic material (inorganic resin) and are each a monolayer film or a multilayer film. The base coat film 28 is the base of the semiconductor film and can prevent impurity diffusion from the glass substrate 21GS, which constitutes the array substrate 21, into the semiconductor film. The gate insulating film 29 is interposed between the semiconductor film and the first metal film and keeps them insulated from each other. To be specific, the gate insulating film 29 keeps the semiconductor portion 24D and gate electrode 24A insulated from each other, as illustrated in FIG. 4. The first interlayer insulating film 30 and the second interlayer insulating film 31 are interposed between the first and second metal films and keep them insulated from each other. To be specific, the first interlayer insulating film 30 and the second interlayer insulating film 31 keep the gate wiring line 26 and source wiring line 27 insulated from each other at their intersection, and keep the gate electrode 24A insulated from the source electrode 24B and drain electrode 24C. In this embodiment, the first interlayer insulating film 30 is made of silicon oxide (SiO₂) containing at least silicon and oxygen. The second interlayer insulating film 31 is made of silicon nitride (SiNₓ) containing at least silicon and nitrogen. The protective film 32 is disposed in a higher layer than the second metal film and protects structures formed from the second metal film (e.g., the source wiring lines 27, the source electrodes 24B, and the drain electrodes 24C). Further, the protective film 32 is interposed between the second metal film and the conductive film (e.g., the transparent electrode film) disposed in a higher layer than the protective film 32, and the protective film 32 can keep them insulated from each other. Like the second interlayer insulating film 31, the protective film 32 is made of silicon nitride containing at least silicon and nitrogen.

The configuration of the TFTs 24 will be detailed. As illustrated in FIG. 4, each TFT 24 is a so-called top-gate type, in which the gate electrode 24A is positioned in a higher layer than the semiconductor portion 24D. The semiconductor pattern portion 33 included in the TFT 24 extends along the X-axis direction and has a middle portion constituting the semiconductor portion 24D overlapping the gate electrode 24A. Both end portions of the semiconductor pattern portion 33 interposing the semiconductor portion 24D therebetween in the X-axis direction constitute a pair of low-resistance portions 24E not overlapping the gate electrode 24A. The pair of low-resistance portions 24E is directly connected to both ends of the semiconductor portion 24D in the X-axis direction. The gate insulating film 29 is selectively provided in an area overlapping the gate electrode 24A. That is, the gate insulating film 29 has the same pattern as the pattern of the structure formed from the first metal film. In the production of the array substrate 21, the gate insulating film 29 and the first metal film are formed continuously, and the gate insulating film 29 undergoes patterning together with the first metal film.

As illustrated in FIG. 4, the source electrode 24B is disposed so as to overlap at least a part of one (on the left side in FIG. 4) of the pair of low-resistance portions 24E. In the first interlayer insulating film 30 and second interlayer insulating film 31 interposed between the source electrode 24B and this low-resistance portions 24E is a source contact hole (contact hole) CHS provided in a position overlapping both of the source electrode 24B and low-resistance portion 24E so as to communicate with the source electrode 24B and low-resistance portion 24E with each other. The source electrode 24B and the low-resistance portions 24E are mutually connected via the source contact hole CHS. The drain electrode 24C is disposed so as to overlap at least a part of the other one (on the right side in FIG. 4) of the pair of low-resistance portions 24E. In the first interlayer insulating film 30 and second interlayer insulating film 31 interposed between the drain electrode 24C and the other low-resistance portion 24E is a drain contact hole (contact hole) CHD provided in a position overlapping both of the drain electrode 24C and other low-resistance portion 24E so as to communicate with the drain electrode 24C and other low-resistance portion 24E with each other. The drain electrode 24C and the other low-resistance portion 24E are mutually connected via the drain contact hole CHD.

In the array substrate 21 according to this embodiment, the second interlayer insulating film 31 made of silicon nitride is disposed in a higher layer than the first interlayer insulating film 30, and the protective film 32 made of silicon nitride is disposed in a higher layer than the second interlayer insulating film 31. The second interlayer insulating film 31 and protective film 32, both made of silicon nitride, each contain hydrogen (H₂). The reason why the second interlayer insulating film 31 and the protective film 32 contain hydrogen is that they contain hydride gases, such as silane gas (SiH₄), tetraethoxysilane gas (TEOS: Tetraethyl orthosilicate), and ammonia gas (NH₃), as raw material gases for use in film formation. In addition, for the transparent electrode film in a higher layer than the protective film 32, hydrogen gas is sometimes used in the film formation in order to improve conductivity or other reasons; in this case, the pixel electrodes 25, which are formed from the transparent electrode film, also contain hydrogen. The hydrogen contained in these second interlayer insulating film 31, protective film 32, and pixel electrode 25 may possibly diffuse downward with time and eventually diffuse into the semiconductor portion 24D. The hydrogen, upon diffusing into the semiconductor portion 24D, acts as a reducing agent to cause a reduction reaction, i.e., oxygen extraction, thereby advancing resistance reduction of the semiconductor portion 24D (i.e., characteristic deterioration), so that the threshold voltage of the TFT 24 may possibly drop. It is noted that the second interlayer insulating film 31, the protective film 32, and the pixel electrode 25 contain a reducing agent other than hydrogen in some cases; the reducing agent other than hydrogen may possibly diffuse into the semiconductor portion 24D, thereby reducing the resistance of the semiconductor portion 24D.

In this regard, in this embodiment, the first interlayer insulating film 30, which is disposed in a lower layer than the second interlayer insulating film 31, protective film 32, and transparent electrode film, has the following configuration in a higher layer than the semiconductor portion 24D. That is, the first interlayer insulating film 30 is made of silicon oxide containing at least silicon and oxygen and includes, as illustrated in FIG. 4, a first layer 30A, and a second layer 30B positioned in a higher layer than the first layer 30A and having a lower oxygen content (lower content concentration of the oxygen) than the first layer 30A. Moreover, the first interlayer insulating film 30 includes a third layer 30C positioned in a higher layer than the second layer 30B and having a higher oxygen content than the second layer 30B. It is noted that FIG. 4 illustrates the formation area of the second layer 30B in the first interlayer insulating film 30 (an area with a low oxygen content) by using a hatch.

As described above, the second layer 30B of the first interlayer insulating film 30 has a lower oxygen content than the first layer 30A and thus includes more dangling bonds than the first layer 30A. Accordingly, even if the reducing agents, such as hydrogen, contained in the second interlayer insulating film 31, protective film 32, and pixel electrode 25 diffuse downward with time, these many dangling bonds included in the second layer 30B can efficiently trap the reducing agents, such as hydrogen.

Consequently, the reducing agents, such as hydrogen, contained in the second interlayer insulating film 31, protective film 32, and pixel electrode 25 are less likely to pass through the first interlayer insulating film 30 and are hence less likely to diffuse into the semiconductor portion 24D, which is disposed in a lower layer than the first interlayer insulating film 30. Moreover, since the first interlayer insulating film 30 includes, in a lower layer than the second layer 30B, the first layer 30A having a higher oxygen content than the second layer 30B, the reducing agent, such as hydrogen, trapped by the second layer 30B is less likely to diffuse again into the semiconductor portion 24D. As described above, the semiconductor portion 24D is less likely to undergo resistance reduction (characteristic deterioration) resulting from the reducing agent, such as hydrogen, so that the threshold voltage of the TFT 24 is less likely to drop, and thus an off leak current is less likely to flow through the semiconductor portion 24D. That is, the electrical characteristics of the TFT 24 can be stabilized, and low power consumption can be achieved. It is noted that the second layer 30B is thinner than the first layer 30A and third layer 30C; for instance, the thickness measures 20 nm or less, which is preferable to optimize the amount of the reducing agent, such as hydrogen, trapped by the dangling bonds so as not to be excess.

Furthermore, as illustrated in FIG. 4, since the first interlayer insulating film 30 includes, in a higher layer than the second layer 30B, the third layer 30C having a higher oxygen content than the second layer 30B, the base of the second interlayer insulating film 31 (different film), which is formed in a higher layer than the first interlayer insulating film 30, is the third layer 30C. That is, the second layer 30B can be avoided from direct contact with the second interlayer insulating film 31, which is formed in a higher layer than the first interlayer insulating film 30, and hence, even when the second interlayer insulating film 31 is formed in a higher layer than the first interlayer insulating film 30, the second layer 30B is less likely to undergo change in its layer quality due to this formation. To be specific, if the second layer 30B were in direct contact with the second interlayer insulating film 31, the second layer 30B to be a base would undergo change in its layer quality during the formation of the second interlayer insulating film 31, thereby possibly decreasing the dangling bonds. In contrast to this, since the second interlayer insulating film 31 is in direct contact with the third layer 30C, which has a higher oxygen content than the second layer 30B, and is thus not in direct contact with the second layer 30B, the second layer 30B is less likely to undergo change in its layer quality and is thus more likely to keep on having a lower oxygen content than the first layer 30A, that is, the second layer 30B is more likely to keep on including more dangling bonds than the first layer 30A. This increases the certainty that the second layer 30B exhibits the function of trapping the reducing agent, such as hydrogen.

Further, the third layer 30C has an oxygen content equal to that of the first layer 30A and has layer quality equal to that of the first layer 30A.

Accordingly, the reducing agent, such as hydrogen, trapped by the second layer 30B interposed between the first layer 30A and third layer 30C is less likely to diffuse both below the first layer 30A and above the third layer 30C. In addition, the first layer 30A and the third layer 30C can be formed under equal conditions in forming the first interlayer insulating film 30, thus offering high productivity.

Further, since the first layer 30A, which has a higher oxygen content than the second layer 30B, is thicker than the second layer 30B, the reducing agent, such as hydrogen, trapped by the second layer 30B is less likely to diffuse again into the semiconductor portion 24D.

Further, the second layer 30B may be amorphous. That is, the second layer 30B may be made of silicon oxide containing oxygen, or amorphous silicon containing almost no oxygen. The second layer 30B that is made of amorphous silicon includes more dangling bonds than the second layer 30B that is made of silicon oxide. Accordingly, the dangling bonds included in the second layer 30B can trap more reducing agents, such as hydrogen, thereby preventing an event where the reducing agent, such as hydrogen, diffuses into the semiconductor portion 24D.

The liquid crystal panel 11 according to this embodiment is structured as described above. Next, a method for manufacturing the liquid crystal panel 11 will be described. The method for manufacturing the liquid crystal panel 11 includes the following process steps: producing the counter substrate 20; producing the array substrate 21 (producing a semiconductor device); and joining together the counter substrate 20 and array substrate 21 as produced. The following describes the step of producing the array substrate.

The step of producing the array substrate includes at least the following: a first step of forming the base coat film 28; a second step of forming and patterning the semiconductor film; a third step of forming the gate insulating film 29; a fourth step of forming and patterning the first metal film; a fifth step of forming the first interlayer insulating film 30; a sixth step of forming and patterning the second interlayer insulating film 31; a seventh step of forming and patterning the second metal film; and an eighth step of forming the protective film 32. It is noted that the step of producing the array substrate includes, after the eighth step, forming and patterning the transparent electrode film, and forming the alignment film. Among the foregoing process steps, the fifth and sixth steps will be detailed mainly.

It is noted that the foregoing word “patterning” refers to film processing based on typical photolithography. To be specific, a workpiece film undergoes processing, i.e., patterning by forming a photoresist film onto the workpiece film, followed by exposing the photoresist film via a photomask having a predetermined opening pattern by the use of an exposure apparatus, followed by developing the photoresist film, followed by etching via the developed photoresist film.

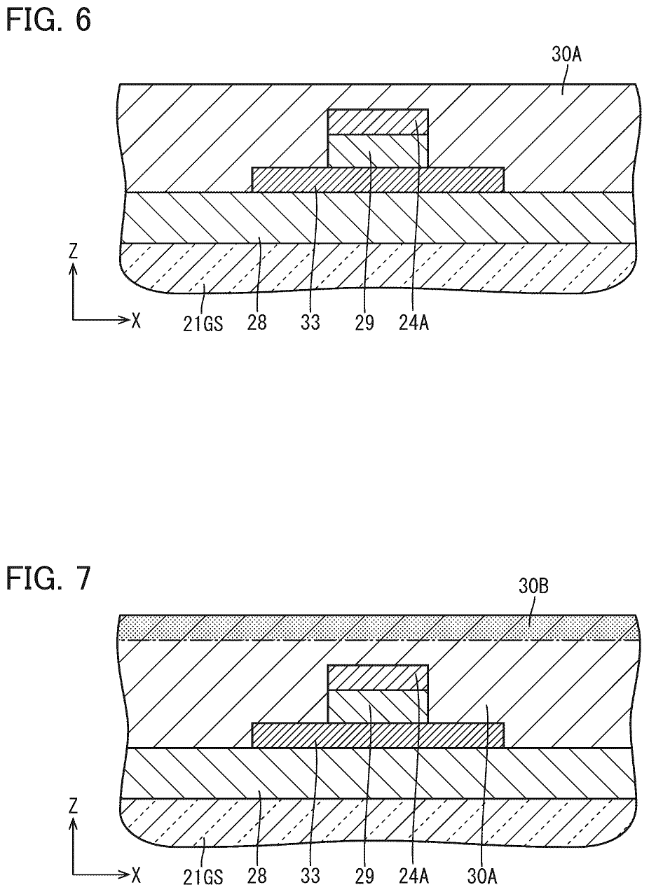

The fourth step is followed by, as illustrated in FIG. 5, patterning the first metal film together with the gate insulating film 29, followed by the fifth step. At a predetermined timing between the fourth and seventh steps, the semiconductor pattern portion 33, which is formed from a part of the semiconductor film, selectively undergoes resistance reduction. In the fifth step, the glass substrate 21GS after the fourth step is accommodated in a chamber (processing chamber) of a chemical-vapor-deposition (CVD) apparatus. The next is supplying radio-frequency (RF) electric power from an RF high-frequency power source while introducing raw material gases into the chamber, to thus provide the chamber's inside with energy through, for instance, plasma discharge to cause a chemical reaction to occur. This can adsorb and deposit a desired film onto the uppermost layer of the glass substrate 21GS (on a side in a higher layer than the first metal film). To be specific, until a lapse of a predetermined time from the start of the fifth step, silane gas (SiH₄), nitrous oxide gas (N₂O), and a noble gas, such as argon gas (Ar), are supplied as raw material gases into the chamber of the CVD apparatus individually at predetermined flow rates. Accordingly, the first layer 30A of the first interlayer insulating film 30 is formed in a higher layer than the first metal film, as illustrated in FIG. 6. The first layer 30A is made of silicon oxide.

After a lapse of a predetermined time from the start of the fifth step, and after the completion of the formation of the first layer 30A, the next is decreasing, among the raw material gases that are introduced into the chamber, the flow rate of the nitrous oxide gas gradually to stop supplying the nitrous oxide gas, or to maintain the flow rate of the nitrous oxide gas at a decreased rate and gradually lower the RF electric power that is supplied from the RF high-frequency power source. At this time, the flow rates of the silane gas and noble gas among the raw material gases are maintained at the same rates as those for forming the first layer 30A. Thus, within the chamber, the second layer 30B is formed in a higher layer than the first layer 30A, as illustrated in FIG. 7, through plasma discharge under an environment where the silane gas and the noble gas are mainly present.

The formed second layer 30B is made of silicon oxide having a lower oxygen content than the first layer 30A, or amorphous silicon containing almost no oxygen. The oxygen content of the second layer 30B depends mainly on the flow rate of the nitrous oxide gas; the oxygen content of the second layer 30B decreases as the flow rate of the nitrous oxide gas decreases. Hence, to form the second layer 30B made of amorphous silicon, it is preferable to stop supplying the nitrous oxide gas during the film formation. The time for forming the second layer 30B (the time for reducing the flow rate of the nitrous oxide gas when compared with the time for forming the first layer 30A) is shorter than the time for forming the first layer 30A. Accordingly, the second layer 30B is thinner than the first layer 30A.

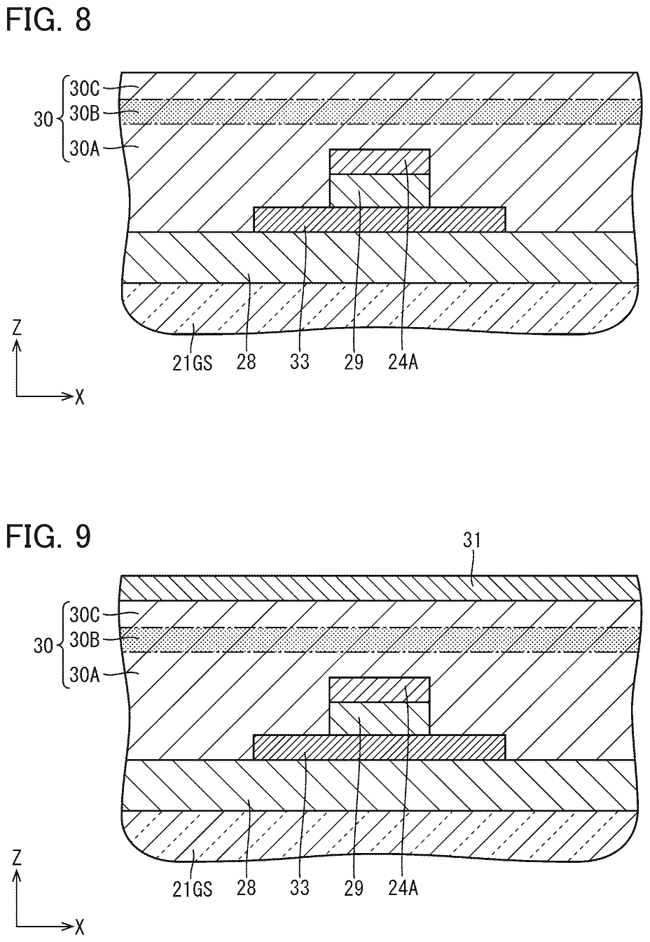

After a lapse of a predetermined time from the stop of the supply of the nitrous oxide gas or from the decrease in the flow rate of the nitrous oxide gas, and after the completion of the formation of the second layer 30B, the next is restarting, among the raw material gases that are introduced into the chamber, the supply of the nitrous oxide gas to gradually increase its flow rate, or to gradually increase the flow rate of the nitrous oxide gas and gradually increase the RF electric power that is supplied from the RF high-frequency power source. At this time, the flow rate of the nitrous oxide gas is set back to the same rate as that for forming the first layer 30A, and the RF electric power supplied from the RF high-frequency power source is set back to the same value as that for forming the first layer 30A. Further, the flow rates of the silane gas and noble gas among the raw material gases are maintained at the same rates as those for forming the first layer 30A and second layer 30B. Accordingly, the third layer 30C is formed in a higher layer than the second layer 30B, as illustrated in FIG. 8. The third layer 30C is made of silicon oxide. The third layer 30C has an oxygen content that is higher than that of the second layer 30B and is equal to that of the first layer 30A.

After a lapse of a predetermined time from the increase in the flow rate of the nitrous oxide gas, and after the completion of the formation of the third layer 30C, the first interlayer insulating film 30 of three-ply structure is formed, and the fifth step is completed. The foregoing fifth step is followed by the sixth step. The sixth step is, as illustrated in FIG. 9, forming the second interlayer insulating film 31 in a higher layer than the first interlayer insulating film 30. The formation of the second interlayer insulating film 31 uses the CVD apparatus, like the formation in the fifth step, and uses, for instance, silane gas, tetraethoxysilane gas, and ammonia gas as raw material gases. Thus, the formed second interlayer insulating film 31 contains hydrogen as a reducing agent. The sixth step is forming the second interlayer insulating film 31, followed by forming a photoresist film in a higher layer than the second interlayer insulating film 31, followed by exposing the photoresist film by the use of the exposure apparatus and a photomask having a predetermined opening pattern (both of the exposure apparatus and photomask are not shown), followed by developing the photoresist film. Accordingly, a photoresist pattern having a shape with the photomask's opening pattern transferred remains, and the second interlayer insulating film 31 and the first interlayer insulating film 30 disposed therebelow undergo etching by the use of the remaining photoresist pattern as a mask. Accordingly, the source contact hole CHS and the drain contact hole CHD are individually provided in the first interlayer insulating film 30 and second interlayer insulating film 31 in a communicating manner (see FIG. 4). Thereafter, the seventh step is performed, in which the second metal film is formed and patterned to provide the source electrode 24B, the drain electrode 24C, and other components (see FIG. 4).

The foregoing sixth step is performed, in which the second interlayer insulating film 31 is formed in a higher layer than the first interlayer insulating film 30; here, the reducing agent, such as hydrogen, contained in the second interlayer insulating film 31 may possibly diffuse into the semiconductor portion 24D therebelow. In this regard, in the fifth step, since the second layer 30B having a lower oxygen content than the first layer 30A is formed when the first interlayer insulating film 30 is formed, trapping the reducing agent, such as hydrogen, by the use of the dangling bonds included in the second layer 30B can prevent an event where the reducing agent, such as hydrogen, diffuses into the semiconductor portion 24D even if the reducing agent, such as hydrogen, tries to intrude from the second interlayer insulating film 31 into the semiconductor portion 24D. Moreover, since the first interlayer insulating film 30 includes, in a lower layer than the second layer 30B, the first layer 30A having a higher oxygen content than the second layer 30B, the reducing agent, such as hydrogen, trapped by the second layer 30B is less likely to diffuse again into the semiconductor portion 24D. As described above, the semiconductor portion 24D is less likely to undergo characteristic deterioration resulting from the reducing agent, such as hydrogen.

Moreover, when the first interlayer insulating film 30 is provided in the fifth step, the first layer 30A, the second layer 30B, and the third layer 30C having their layer qualities different from each other can be continuously formed by regulating the flow rate of the nitrous oxide gas included in the raw material gases that are supplied to the CVD apparatus, and by regulating the RF electric power from the RF high-frequency power source. This can form the first interlayer insulating film 30 of three-ply structure without pulling and retracting the glass substrate 21GS out of and into the chamber of the CVD apparatus every time each of the layers 30A, 30B, and 30C is formed, so that high productivity can be achieved.

Furthermore, the second interlayer insulating film 31 formed through the sixth step is in direct contact with the third layer 30C, which constitutes the base of the first interlayer insulating film 30, but is not in direct contact with the second layer 30B. Thus, the surface of the second layer 30B is avoided from being exposed to the raw material gases of the second interlayer insulating film 31 when the second interlayer insulating film 31 is formed in the sixth step. Accordingly, the second layer 30B is less likely to undergo change in its layer quality, thus preventing an event where the dangling bonds decrease. This increases the certainty that the second layer 30B exhibits the function of trapping the reducing agent, such as hydrogen.

As described above, the array substrate (semiconductor device) 21 according to this embodiment includes the following: the semiconductor portion 24D formed from a part of the semiconductor film; and the first interlayer insulating film (first insulating film) 30 disposed in a higher layer than the semiconductor film and containing at least silicon and oxygen. The first interlayer insulating film 30 includes the first layer 30A, and the second layer 30B positioned in a higher layer than the first layer 30A, and having a lower oxygen content than the first layer 30A.

The second layer 30B of the first interlayer insulating film 30 containing at least silicon and oxygen has a lower oxygen content than the first layer 30A and thus includes more dangling bonds than the first layer 30A. Accordingly, even if hydrogen and other things present in a higher layer than the first interlayer insulating film 30 try to intrude into the semiconductor portion 24D, trapping the hydrogen and other things by the use of the dangling bonds included in the second layer 30B can prevent an event where the hydrogen and other things diffuse into the semiconductor portion 24D. Moreover, the first interlayer insulating film 30 includes, in a lower layer than the second layer 30B, the first layer 30A having a higher oxygen content than the second layer 30B, so that the hydrogen and other things trapped by the second layer 30B are less likely to diffuse again into the semiconductor portion 24D. As such, the semiconductor portion 24D is less likely to undergo characteristic deterioration resulting from the hydrogen and other things.

The first interlayer insulating film 30 also includes the third layer 30C positioned in a higher layer than the second layer 30B, and having a higher oxygen content than the second layer 30B. For forming the second interlayer insulating film 31 as a separate film in a higher layer than the first interlayer insulating film 30, the base of the second interlayer insulating film 31, which is the separate film to be formed, is the third layer 30C. That is, the second layer 30B can be avoided from direct contact with the second interlayer insulating film 31, which is formed in a higher layer than the first interlayer insulating film 30, and hence, even when the second interlayer insulating film 31 is formed in a higher layer than the first interlayer insulating film 30, the second layer 30B is less likely to undergo change in its layer quality due to this formation. This facilitates maintaining the second layer 30B to have a lower oxygen content than the first layer 30A, and increases the certainty that the second layer 30B exhibits the function of trapping the hydrogen and other things.

Further, the third layer 30C has an oxygen content equal to that of the first layer 30A. The first layer 30A and the third layer 30C have equal layer quality. Accordingly, the hydrogen and other things trapped by the second layer 30B interposed between the first layer 30A and third layer 30C are less likely to diffuse both below the first layer 30A and above the third layer 30C. In addition, the first layer 30A and the third layer 30C can be formed under equal conditions in forming the first interlayer insulating film 30, thus offering high productivity.

The array substrate (semiconductor device) 21 also includes the second interlayer insulating film (second insulating film) 31 disposed in a higher layer than the first interlayer insulating film 30, and containing at least silicon and nitrogen. The second interlayer insulating film 31, which contains at least silicon and nitrogen, contains hydrogen and other things when it is formed. Hence, the hydrogen and other things contained in the second interlayer insulating film 31 may possibly diffuse into the semiconductor portion 24D via the first interlayer insulating film 30, which is disposed in a lower layer than the second interlayer insulating film 31.

In this regard, since the second layer 30B includes many dangling bonds, trapping the hydrogen and other things diffusing from the second interlayer insulating film 31 by the use of the dangling bonds included in the second layer 30B can prevent an event where the hydrogen and other things diffuse into the semiconductor portion 24D.

Further, the first layer 30A is thicker than the second layer 30B. The first layer 30A having a higher oxygen content than the second layer 30B is formed to be thicker than the second layer 30B, so that the hydrogen and other things trapped by the second layer 30B are less likely to diffuse again into the semiconductor portion 24D.

The array substrate (semiconductor device) 21 also includes the following: the gate insulating film (third insulating film) 29 disposed in a higher layer than the semiconductor film and in a lower layer than the first interlayer insulating film 30; the gate electrode (first electrode) 24A formed from a part of the first metal film disposed in a higher layer than the gate insulating film 29 and in a lower layer than the first interlayer insulating film 30; the source electrode 24B and drain electrode 24C (second electrode) formed from a part of the second metal film disposed in a higher layer than the first interlayer insulating film 30; and the low-resistance portion 24E formed from a part of the semiconductor film, coupling to the semiconductor portion 24D, and processed to have a lower resistance than the semiconductor portion 24D. The gate electrode 24A is disposed so as to overlap the semiconductor portion 24D. The gate insulating film 29 is disposed so as to overlap the semiconductor portion 24D and the gate electrode 24A. The source electrode 24B and the drain electrode 24C are disposed so as to overlap at least a part of the low-resistance portion 24E. The source contact hole CHS (contact hole) connecting the source electrode 24B and one of the low-resistance portions 24E together is provided in the first interlayer insulating film 30 overlapping both of the source electrode 24B and low-resistance portion 24E. The drain contact hole CHD (contact hole) connecting the drain electrode 24C and the other low-resistance portion 24E together is provided in the first interlayer insulating film 30 overlapping both of the drain electrode 24C and low-resistance portion 24E. The source electrode 24B and the low-resistance portion 24E are connected together via the source contact hole CHS of the first interlayer insulating film 30 to have the same potential. The drain electrode 24C and the other low-resistance portion 24E are connected together via the drain contact hole CHD of the first interlayer insulating film 30 to have the same potential. Supplying a predetermined or higher level of potential to the gate electrode 24A overlapping the semiconductor portion 24D with the gate insulating film 29 interposed therebetween, produces a channel region in the semiconductor portion 24D.

Accordingly, a signal that is supplied from the source electrode 24B and drain electrode 24C to the low-resistance portions 24E is configured to be transmitted through the channel region of the semiconductor portion 24D.

The second layer 30B traps the hydrogen and other things to prevent an event where the semiconductor portion 24D undergoes characteristic deterioration, so that an off leak current is less likely to flow through the semiconductor portion 24D. This can reduce power consumption.

Further, the second layer 30B is amorphous. The amorphous second layer 30B includes more dangling bonds. This can trap more hydrogen and other things by the use of the dangling bonds included in the second layer 30B, and can thus prevent an event where the hydrogen and other things diffuse into the semiconductor portion 24D.

Further, the liquid crystal panel (display device) 11 according to this embodiment includes the foregoing array substrate 21, and the counter substrate 20 disposed so as to face the array substrate 21. In this display device, the hydrogen and other things are less likely to diffuse into the semiconductor portion 24D, so that the semiconductor portion 24D is less likely to undergo characteristic deterioration. This provides favorable display quality.

The method for manufacturing the array substrate 21 according to this embodiment includes the following: providing the semiconductor portion 24D by forming the semiconductor film, followed by patterning the semiconductor film as formed; and providing, in a higher layer than the semiconductor film, the first interlayer insulating film 30 containing at least silicon and oxygen. The providing of the first interlayer insulating film 30 is forming the first layer 30A, followed by forming, in a higher layer than the first layer 30A, the second layer 30B having a lower content of the oxygen than the first layer 30A.

The second layer 30B of the first interlayer insulating film 30 containing at least silicon and oxygen has a lower oxygen content than the first layer 30A and thus includes more dangling bonds than the first layer 30A. Accordingly, even if hydrogen and other things present in a higher layer than the first interlayer insulating film 30 try to intrude into the semiconductor portion 24D, trapping the hydrogen and other things by the use of the dangling bonds included in the second layer 30B can prevent an event where the hydrogen and other things diffuse into the semiconductor portion 24D. Moreover, the first interlayer insulating film 30 includes, in a lower layer than the second layer 30B, the first layer 30A having a higher oxygen content than the second layer 30B, so that the hydrogen and other things trapped by the second layer 30B are less likely to diffuse again into the semiconductor portion 24D. As such, the semiconductor portion 24D is less likely to undergo characteristic deterioration resulting from the hydrogen and other things.

Further, the providing of the first interlayer insulating film 30 is supplying at least silane gas, nitrous oxide gas, and a noble gas as raw materials to a chemical-vapor-deposition (CVD) apparatus to form the first layer 30A, followed by supplying at least the silane gas and noble gas as raw materials to the CVD apparatus to form the second layer 30B. The first layer 30A can be formed by supplying at least the silane gas, the nitrous oxide gas, and the noble gas as raw materials to the CVD apparatus. Then, stopping supplying the nitrous oxide gas, or decreasing the flow rate of the nitrous oxide gas and continuing to supply at least the silane gas and the noble gas can form the second layer 30B having a lower oxygen content than the first layer 30A. The first layer 30A and second layer 30B with different layer qualities can be formed continuously in this way, thereby achieving high productivity.

Further, the providing of the first interlayer insulating film 30 is, after forming the second layer 30B, supplying at least the silane gas, the nitrous oxide gas, and the noble gas as raw materials to the CVD apparatus to form, in a higher layer than the second layer 30B, the third layer 30C having a higher content of the oxygen than the second layer 30B. Supplying at least the silane gas, the nitrous oxide gas, and the noble gas as raw materials to the CVD apparatus to form the first layer 30A is followed by forming the second layer 30B by pausing the supply of the nitrous oxide gas, or by decreasing the flow rate of the nitrous oxide gas and continuing the supply of at least the silane gas and noble gas. Then, restarting supplying the nitrous oxide gas, or increasing the flow rate of the nitrous oxide gas and continuing to supply at least the silane gas, the nitrous oxide gas, and the noble gas can form the third layer 30C having a higher oxygen content than the second layer 30B. The first layer 30A, second layer 30B, and third layer 30C with different layer qualities can be formed continuously in this way, thereby achieving high productivity. For forming the second interlayer insulating film 31 as a separate film in a higher layer than the first interlayer insulating film 30 provided in this way, the base of the second interlayer insulating film 31, which is the separate film to be formed, is the third layer 30C. That is, the second layer 30B can be avoided from direct contact with the second interlayer insulating film 31, which is formed in a higher layer than the first interlayer insulating film 30, and hence, even when the second interlayer insulating film 31 is formed in a higher layer than the first interlayer insulating film 30, the second layer 30B is less likely to undergo change in its layer quality due to this formation. This facilitates maintaining the second layer 30B to have a lower oxygen content than the first layer 30A, and increases the certainty that the second layer 30B exhibits the function of trapping the hydrogen and other things.

### Second Embodiment

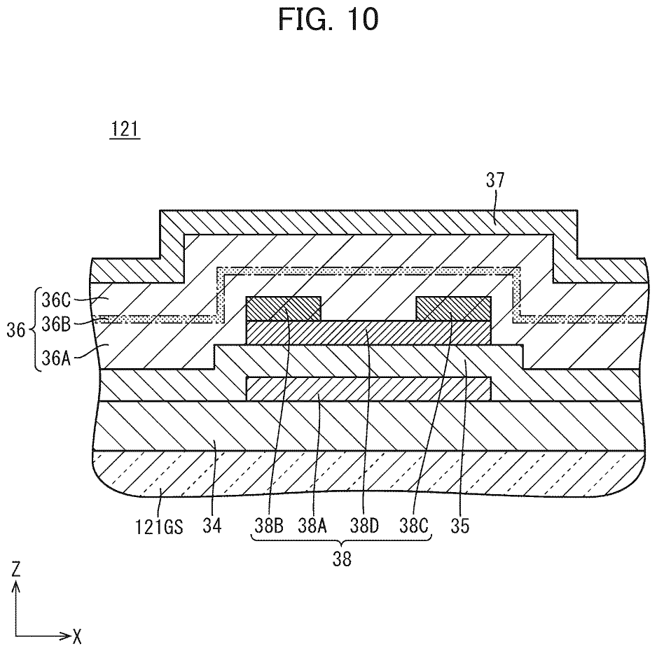

A second embodiment will be described with reference to FIG. 10.

The second embodiment will describe a modified film configuration in an array substrate 121 and a modified configuration in TFTs 38. It is noted that redundancies of structure, action, and effect that are similar to those in the first embodiment will not be described.

The array substrate 121 according to this embodiment includes a glass substrate 121GS, on which, as illustrated in FIG. 10, at least a base coat film 34, a third metal film, a gate insulating film (fourth insulating film) 35, a semiconductor film, a fourth metal film, a first interlayer insulating film (first insulating film) 36, and a second interlayer insulating film (second insulating film) 37 are stacked sequentially from the bottom (from the glass substrate 121GS). It is noted that other than the foregoing films, a transparent electrode film disposed in a higher layer than the second interlayer insulating film 37 to constitute the pixel electrodes 25, an alignment film disposed on the innermost surface (uppermost layer) of the array substrate 121 to align the liquid crystal molecules, and other components are formed on the glass substrate 121GS of the array substrate 121. Further, the protective film 32 described in the first embodiment may be formed in a higher layer than the second interlayer insulating film 37.

Like the first and second metal films described in the first embodiment, each of the third and fourth metal films is a monolayer film made of a single kind of metal material, a multilayer film made of different kinds of metal material (conductive material), or an alloy, and thus, each of these films has conductivity and light-blocking capability. The third metal film is, for example, a monolayer film of molybdenum tungsten (MoW), or a multilayer film of tungsten (W)-tantalum nitride (TaN). The third metal film constitutes, but not limited to, the gate wiring lines 26 and other components (see FIG. 3). The fourth metal film is, for instance, a multilayer film of titanium (Ti)-aluminum (Al)—Ti. The fourth metal film constitutes, but not limited to, the source wiring lines 27 and other components (see FIG. 3).

The semiconductor film is made of oxide semiconductor material, like the semiconductor film described in the first embodiment. More specifically, the semiconductor film is formed from, for example, a thin oxide film containing indium (In), gallium (Ga), and zinc (Zn), which are kinds of oxide semiconductors. The thin oxide film containing indium (In), gallium (Ga), and zinc (Zn) is amorphous or crystalline. The semiconductor film according to this embodiment is not processed to have a low resistance and is thus formed as a non-resistance-reduced part in its entirety.

The base coat film 34, the gate insulating film 35, the first interlayer insulating film 36, and the second interlayer insulating film 37 are each made of inorganic material and are each a monolayer film or a multilayer film, like the base coat film 28, gate insulating film 29, first interlayer insulating film 30, second interlayer insulating film 31, and the protective film 32 described in the first embodiment. The base coat film 34 is the bases of the third metal film and gate insulating film 35. The gate insulating film 35 is interposed between the third metal film and the semiconductor film and keeps them insulated from each other. The first interlayer insulating film 36 and the second interlayer insulating film 37 are disposed in a higher layer than the fourth metal film and cover a structure formed from the semiconductor film (e.g., a semiconductor portion 38D), and a structure formed from the fourth metal film (e.g., source electrodes 38B and drain electrodes 38C). In this embodiment, the first interlayer insulating film 36 is made of silicon oxide containing at least silicon and oxygen. The second interlayer insulating film 37 is made of silicon nitride containing at least silicon and nitrogen.

Each TFT 38 includes the following as illustrated in FIG. 10: a gate electrode (third electrode) 38A connected to the gate wiring line 26; the source electrode (fourth electrode) 38B connected to the source wiring line 27: the drain electrode (fourth electrode) 38C connected to the pixel electrode 25; and the semiconductor portion 38D connected to the source electrode 38B and drain electrode 38C (see FIG. 3). The TFT 38 is driven based on a scanning signal supplied to the gate electrode 38A by the gate wiring line 26. The scanning signal includes a potential (high potential) higher than the threshold voltage of the TFT 38. Accordingly, a channel region is produced in the semiconductor portion 38D, and thus, a potential based on an image signal supplied to the source electrode 38B by the source wiring line 27 is supplied to the drain electrode 38C via the channel region of the semiconductor portion 38D. As a result, the pixel electrode 25 is charged to the potential based on the image signal.

The configuration of the TFTs 38 will be detailed. As illustrated in FIG. 10, each TFT 38 is a so-called bottom-gate TFT, in which the gate electrode 38A is positioned in a lower layer than the semiconductor portion 38D. The gate electrode 38A is formed from a part of the third metal film.

The semiconductor portion 38D is formed from a part of the semiconductor film. The gate electrode 38A and the semiconductor portion 38D each extend along the X-axis direction and are disposed so as to overlap each other. The gate electrode 38A and semiconductor portion 38D overlapping each other are kept insulated from each other by the gate insulating film 35 interposed therebetween. The gate insulating film 35 in this embodiment extends flatly and extends also to a region not overlapping the gate electrode 38A and semiconductor portion 38D. Each of the source electrode 38B and drain electrode 38C is formed from a part of the fourth metal film. The source electrode 38B is disposed so as to overlap one end (on the left side in FIG. 10) of the semiconductor portion 38D in the X-axis direction. The drain electrode 38C is disposed so as to overlap the other end (on the right side in FIG. 10) of the semiconductor portion 38D in the X-axis direction. No insulating film is interposed between the source electrode 38B and the semiconductor portion 38D, and between the drain electrode 38C and the semiconductor portion 38D; thus, the source electrode 38B and the drain electrode 38C are in direct contact with the semiconductor portion 38D without contact holes.

In this embodiment, the first interlayer insulating film 36 disposed in a higher layer than the semiconductor portion 38D and in a lower layer than the second interlayer insulating film 37 and transparent electrode film is made of silicon oxide containing at least silicon and oxygen, and as illustrated in FIG. 10, the first interlayer insulating film 36 includes a first layer 36A, a second layer 36B positioned in a higher layer than the first layer 36A and having a lower oxygen content than the first layer 36A, and a third layer 36C positioned in a higher layer than the second layer 36B and having a higher oxygen content than the second layer 36B. It is noted that FIG. 10 illustrates the formation area of the second layer 36B in the first interlayer insulating film 36 (an area with a low oxygen content) by using a hatch.

As described above, the second layer 36B of the first interlayer insulating film 36 has a lower oxygen content than the first layer 36A and thus includes more dangling bonds than the first layer 36A. Accordingly, even if the reducing agents, such as hydrogen, contained in the second interlayer insulating film 37, which is made of silicon nitride, and in the pixel electrode 25, which is formed from a part of the transparent electrode film, diffuse downward with time, these many dangling bonds included in the second layer 36B can efficiently trap the reducing agents, such as hydrogen. Consequently, the reducing agents, such as hydrogen, contained in the second interlayer insulating film 37 and pixel electrode 25 are less likely to pass through the first interlayer insulating film 36 and are hence less likely to diffuse into the semiconductor portion 38D, which is disposed in a lower layer than the first interlayer insulating film 36. Moreover, since the first interlayer insulating film 36 includes, in a lower layer than the second layer 36B, the first layer 36A having a higher oxygen content than the second layer 36B, the reducing agent, such as hydrogen, trapped by the second layer 36B is less likely to diffuse again into the semiconductor portion 38D. As described above, the semiconductor portion 38D is less likely to undergo resistance reduction (characteristic deterioration) resulting from the reducing agent, such as hydrogen, so that the threshold voltage of the TFT 38 is less likely to drop, and thus an off leak current is less likely to flow through the semiconductor portion 38D. That is, the electrical characteristics of the TFT 38 can be stabilized, and low power consumption can be achieved. It is noted that the second layer 36B is thinner than the first layer 36A and third layer 36C; for instance, the thickness measures 20 nm or less, which is preferable to optimize the amount of the reducing agent, such as hydrogen, trapped by the dangling bonds so as not to be excess.

Furthermore, as illustrated in FIG. 10, since the first interlayer insulating film 36 includes, in a higher layer than the second layer 36B, the third layer 36C having a higher oxygen content than the second layer 36B, the base of the second interlayer insulating film 37 (different film), which is formed in a higher layer than the first interlayer insulating film 36, is the third layer 36C. That is, the second layer 30B can be avoided from direct contact with the second interlayer insulating film 37, which is formed in a higher layer than the first interlayer insulating film 36, and hence, even when the second interlayer insulating film 37 is formed in a higher layer than the first interlayer insulating film 36, the second layer 36B is less likely to undergo change in its layer quality due to this formation. To be specific, if the second layer 36B were in direct contact with the second interlayer insulating film 37, the second layer 36B to be a base would undergo change in its layer quality during the formation of the second interlayer insulating film 37, thereby possibly decreasing the dangling bonds. In contrast to this, since the second interlayer insulating film 37 is in direct contact with the third layer 36C, which has a higher oxygen content than the second layer 36B, and is thus not in direct contact with the second layer 36B, the second layer 36B is less likely to undergo change in its layer quality and is thus more likely to keep on having a lower oxygen content than the first layer 36A, that is, the second layer 36B is more likely to keep on including more dangling bonds than the first layer 36A. This increases the certainty that the second layer 36B exhibits the function of trapping the reducing agent, such as hydrogen.

Further, the third layer 36C has an oxygen content equal to that of the first layer 36A and has layer quality equal to that of the first layer 36A.

Accordingly, the reducing agent, such as hydrogen, trapped by the second layer 36B interposed between the first layer 36A and third layer 36C is less likely to diffuse both below the first layer 36A and above the third layer 36C. In addition, the first layer 36A and the third layer 36C can be formed under equal conditions in forming the first interlayer insulating film 36, thus offering high productivity.

Further, since the first layer 36A, which has a higher oxygen content than the second layer 36B, is thicker than the second layer 36B, the reducing agent, such as hydrogen, trapped by the second layer 36B is less likely to diffuse again into the semiconductor portion 38D.

Further, the second layer 36B may be amorphous. That is, the second layer 36B may be made of silicon oxide containing oxygen, or amorphous silicon containing almost no oxygen. The second layer 36B that is made of amorphous silicon includes more dangling bonds than the second layer 36B that is made of silicon oxide. Accordingly, the dangling bonds included in the second layer 36B can trap more reducing agents, such as hydrogen, thereby preventing an event where the reducing agent, such as hydrogen, diffuses into the semiconductor portion 38D.

The array substrate 121 having the foregoing configuration can be manufactured through a method similar to the foregoing method in the first embodiment.

As described above, the array substrate 121 includes the following: the gate insulating film (fourth insulating film) 35 disposed in a lower layer than the semiconductor film; the gate electrode (third electrode) 38A formed from a part of the third metal film disposed in a lower layer than the gate insulating film 35; and the source electrode 38B (fourth electrode) and drain electrode 38C (fourth electrode) formed from a part of the fourth metal film disposed in a higher layer than the semiconductor film and in a lower layer than the first interlayer insulating film 36. The gate electrode 38A is disposed so as to overlap the semiconductor portion 38D. The source electrode 38B and the drain electrode 38C are each disposed so as to overlap a part of the semiconductor portion 38D to be in contact with the semiconductor portion 38D. Supplying a predetermined or higher level of potential to the gate electrode 38A overlapping the semiconductor portion 38D with the gate insulating film 35 interposed therebetween, produces a channel region in the semiconductor portion 38D. Accordingly, a signal that is supplied from the source electrode 38B and drain electrode 38C to the semiconductor portion 38D is configured to be transmitted through the channel region of the semiconductor portion 38D. The second layer 36B traps the hydrogen and other things to prevent an event where the semiconductor portion 38D undergoes characteristic deterioration, so that an off leak current is less likely to flow through the semiconductor portion 38D. This can reduce power consumption.

### Other Embodiments

The technique disclosed in the Specification is not limited to the embodiments described in the forgoing descriptions and drawings. The following embodiments for instance are also encompassed in the technical scope of the present invention.

(1) In the first interlayer insulating film 30, 36, the oxygen content of the first layer 30A, 36A may be different from the oxygen content of the third layer 30C, 36C.

(2) In the first interlayer insulating film 30, 36, the relationship in thickness between the first layer 30A, 36A, the second layer 30B, 36B, and the third layer 30C, 36C can undergo modifications, as appropriate, other than what are illustrated in the drawings. For instance, the second layer 30B, 36B may be as thick as, or thicker than the first layer 30A, 36A. The second layer 30B, 36B may be as thick as, thicker than, or thinner than the third layer 30C, 36C. The first layer 30A, 36A may be as thick as, thicker than, or thinner than the third layer 30C, 36C. Further, the second layer 30B, 36B may have a thickness of 20 nm or more.

(3) In the first interlayer insulating film 30, 36, the third layer 30C, 36C can be omitted. In this case, the base of the second interlayer insulating film 31, 37 is the second layer 30B, 36B of the first interlayer insulating film 30, 36.

(4) The second interlayer insulating film 31, 37 may be made of material other than silicon nitride (e.g., silicon oxide and silicon nitride oxide). Further, the second interlayer insulating film 31, 37 may be a multilayer film formed by stacking a plurality of films made of different materials; in this case, the materials may or may not include silicon nitride.

(5) In the configuration described in the first embodiment, the protective film 32 may be made of material other than silicon nitride (e.g., silicon oxide and silicon oxynitride). Further, the protective film 32 may be a multilayer film formed by stacking a plurality of films made of different materials; in this case, the materials may or may not include silicon nitride.

(6) In the configuration described in the second embodiment, an insulating film may be interposed between the source electrode 38B and the semiconductor portion 38D, and between the drain electrode 38C and the semiconductor portion 38D. In this case, contact holes may be provided in the respective insulating films interposed between the source electrode 38B and the semiconductor portion 38D, and between the drain electrode 38C and the semiconductor portion 38D, and via the contact holes, the source electrode 38B and the drain electrode 38C may be connected to the semiconductor portion 38D.

(7) In the fifth step included in the method for manufacturing the array substrate 21, 121, the flow rates of the silane gas and noble gas, which are the raw material gases of the first interlayer insulating film 30, 36, can be different between the formation of the first layer 30A, 36A, the formation of the second layer 30B, 36B, and the formation of the third layer 30C, 36C. The same is true for the RF electric power.

(8) In the method for manufacturing the array substrate 21, described in the first embodiment, or the array substrate 121, the timing at which the semiconductor pattern portion 33 undergoes resistance reduction may be between the fourth and fifth steps, between the fifth and sixth steps, or between the sixth and seventh steps.

(9) The specific configuration of the films provided in the array substrate 21, 121 can be modified as appropriate, other than the foregoing. For instance, a flattening film made of organic material (e.g., acrylic) may be disposed in a higher layer than the first interlayer insulating film 30, 36.

(10) The TFT 24, 38 may be a double-gate type, in which gate electrodes are disposed so as to overlap the respective upper and lower sides of the semiconductor portion 24D, 38D.

(11) The semiconductor film may be a thin amorphous silicon film or a thin polycrystalline silicon film.

(12) In the non-display region NAA of the array substrate 21, 121, a gate driver circuit (a gate driver monolithic circuit or GDM circuit for short) for supplying a scanning signal to the gate wiring lines 26, or a switch circuit (a source shared driving circuit or SSD circuit for short) for distributing an image signal supplied from the driver 12 to the plurality of source wiring lines 27 may be provided monolithically by the use of each film on the glass substrate 21GS, 121GS.

(13) The array substrate 21, 121 may have a substrate of synthetic resin as a light-transparent substrate, other than the glass substrate 21GS, 121GS.

(14) The driver 12 may be mounted, through chip-on-film (COF), on the flexible substrate 13 mounted on the array substrate 21, 121 through film-on-glass (FOG).

(15) The planar shape of the liquid crystal panel 11 may be, but not limited to, a vertical oblong, a square, a circle, a semicircle, a vertical oval, an ellipse, or a trapezoid.

(16) The liquid crystal panel 11 may display an image in any of, but not limited to, a fringe-field-switching (FFS) mode, a twisted-nematic (TN) mode, a vertical-alignment (VA) mode, and an in-plane-switching (IPS) mode.

(17) Other than the liquid crystal panel 11, the display device may be an organic electro-luminescence (EL) display panel, or a display panel that uses a microencapsulated electrophoretic scheme.

What is claimed is:

1. A semiconductor device comprising:
a semiconductor portion formed from a part of a semiconductor film; and
a first insulating film disposed in a higher layer than the semiconductor film and containing at least silicon and oxygen,
wherein the first insulating film includes
a first layer, and
a second layer positioned in a higher layer than the first layer and having a lower content of the oxygen than the first layer.

2. The semiconductor device according to claim 1, wherein the first insulating film includes a third layer positioned in a higher layer than the second layer and having a higher content of the oxygen than the second layer.

3. The semiconductor device according to claim 2, wherein the third layer has a content of the oxygen equal to a content of the oxygen of the first layer.

4. The semiconductor device according to claim 1, comprising a second insulating film disposed in a higher layer than the first insulating film and containing at least silicon and nitrogen.

5. The semiconductor device according to claim 1, wherein the first layer is thicker than the second layer.

6. The semiconductor device according to claim 1, comprising:
a third insulating film disposed in a higher layer than the semiconductor film and in a lower layer than the first insulating film;
a first electrode formed from a part of a first metal film disposed in a higher layer than the third insulating film and in a lower layer than the first insulating film;
a second electrode formed from a part of a second metal film disposed in a higher layer than the first insulating film; and
a low-resistance portion formed from a part of the semiconductor film, coupling to the semiconductor portion, and processed to have a lower resistance than the semiconductor portion,
wherein the first electrode is disposed so as to overlap the semiconductor portion,
the third insulating film is disposed so as to overlap the semiconductor portion and the first electrode,
the second electrode is disposed so as to overlap at least a part of the low-resistance portion, and
a contact hole connecting the second electrode and the low-resistance portion together is provided in the first insulating film overlapping both of the second electrode and the low-resistance portion.

7. The semiconductor device according to claim 1, comprising:
a fourth insulating film disposed in a lower layer of the semiconductor film;
a third electrode formed from a part of a third metal film disposed in a lower layer than the fourth insulating film; and
a fourth electrode formed from a part of a fourth metal film disposed in a higher layer than the semiconductor film and in a lower layer than the first insulating film,
wherein the third electrode is disposed so as to overlap the semiconductor portion, and
the fourth electrode is disposed so as to overlap a part of the semiconductor portion to be in contact with the semiconductor portion.

8. The semiconductor device according to claim 1, wherein the second layer is amorphous.

9. A display device comprising:
the semiconductor device according to claim 1; and
a counter substrate disposed so as to face the semiconductor device.

10. A method for manufacturing a semiconductor device, comprising:
providing a semiconductor portion by forming a semiconductor film, followed by patterning the semiconductor film as formed; and
providing, in a higher layer than the semiconductor film, a first insulating film containing at least silicon and oxygen,
wherein the providing of the first insulating film comprises forming a first layer, followed by forming, in a higher layer than the first layer, a second layer having a lower content of the oxygen than the first layer.

11. The method for manufacturing the semiconductor device according to claim 10, wherein
the providing of the first insulating film comprises supplying at least a silane gas, a nitrous oxide gas, and a noble gas as raw materials to a chemical-vapor-deposition apparatus to form the first layer, followed by supplying at least the silane gas and the noble gas as raw materials to the chemical-vapor-deposition apparatus to form the second layer.

12. The method for manufacturing the semiconductor device according to claim 11, wherein
the providing of the first insulating film comprises, after forming the second layer, supplying at least the silane gas, the nitrous oxide gas, and the noble gas as raw materials to the chemical-vapor-deposition apparatus to form, in a higher layer than the second layer, a third layer having a higher content of the oxygen than the second layer.
